(19) United States
(12) Patent Application Publication
(10) Pub. No.: US 2021/0287612 A1
(43) Pub. Date: Sep. 16, 2021

(54) DISPLAY DEVICE AND ELECTRONIC DEVICE

(71) Applicant: Shenzhen Royole Technologies Co., Ltd., Shenzhen (CN)

(72) Inventors: Qiangcan Huang, Shenzhen (CN); Zhihe Jin, Shenzhen (CN); Changming Qiu, Shenzhen (CN)

(21) Appl. No.: 17/336,624

(22) Filed: Jun. 2, 2021

Related U.S. Application Data
(63) Continuation of application No. PCT/CN2018/118926, filed on Dec. 3, 2018.

(51) Int. Cl. G09G 3/3266; H01L 27/32

(52) U.S. Cl. CPC G09G 3/3266; H01L 27/3262; H01L 27/3276

(57) ABSTRACT

A display device includes a pixel array including M rows of pixel units, M scanning lines, a first drive module, and a second drive module. An N^{th} scanning line is connected to the pixel units in an N^{th} row and the pixel units (11) in an (N+2)^{th} row. One of the first drive module and the second drive module is connected to the scanning line connected to the pixel units in an odd row and is configured to supply, via the scanning line, a scanning signal and a reset signal to the pixel units in the odd row, and the other of the drive modules is connected to the scanning line connected to the pixel units in an even row and is configured to supply, via the scanning line, a scanning signal and a reset signal to the pixel units in the even row.

### CROSS-REFERENCE TO RELATED APPLICATIONS

This application is a continuation of International Application No. PCT/CN2018/118926, with an international filing date of Dec. 3, 2018, titled “DISPLAY DEVICE AND ELECTRONIC DEVICE,” the entire contents of which are incorporated herein by reference.

### TECHNICAL FIELD

The present disclosure relates to the technical field of display, and in particular, relates to a display device and an electronic device.

### BACKGROUND

In the related art, gate driver on array (GOA) circuit is widely applied in electronic displays such as liquid crystal displays (LCDs), active-matrix organic light-emitting diodes (AMOLEDs), and the like. The GOA circuit is an important part of display devices, and is configured to supply scanning pulse signals to pixel arrays.

In a display device in the related art, generally, two GOA circuits are employed to supply scanning pulse signals to a plurality of rows of pixel units in a pixel array. One GOA circuit supplies a scanning signal Gn to the pixel units, and the other GOA circuit supplies a reset signal Rn to the pixel units. However, with higher and higher requirements imposed by users to resolution of the display device, the number of rows of the pixel array is increased, and the number of stages of each GOA circuit is correspondingly increased. For example, with respect to a display panel with resolution of 1920, two GOA circuits each require 1920 stages. One GOA circuit supplies the scanning signal Gn, and the other GOA circuit supplies the reset signal Rn. In this way, the border of the display device is wide.

### SUMMARY

Embodiments of the present disclosure provide a display device, the display device includes:

a pixel array, including M rows of pixel units;

M scanning lines, an N^{th} scanning line being connected to the pixel units in an N^{th} row and the pixel units in an (N+2)^{th} row, 1≤N, (N+2)≤M, N and M being both a positive integer; and

a first drive module and a second drive module, one of the first drive module and the second drive module being connected to the scanning line connected to the pixel units in an odd row and being configured to supply a scanning signal and a reset signal to the pixel units in the odd row via the scanning line, and the other of the first drive module and the second drive module being connected to the scanning line connected to the pixel units in an even row and being configured to supply a scanning signal and a reset signal to the pixel units in the even row via the scanning line.

Embodiments of the present disclosure further provide an electronic device including the display device as described above.

### BRIEF DESCRIPTION OF THE DRAWINGS

The above described and/or additional aspects and advantages of the present disclosure would be obvious and simple to understand with reference to the description of the embodiments in combination with the accompanying drawings.

FIG. 1 is a schematic structural diagram of a display device according to an embodiment of the present disclosure;

FIG. 2 is a schematic diagram of modules of an electronic device according to an embodiment of the present disclosure;

FIG. 3 is a schematic structural diagram of a pixel unit of the display device according to an embodiment of the present disclosure;

FIG. 4 is a schematic working timing diagram of the pixel unit of the display device according to an embodiment of the present disclosure;

FIG. 5 is a schematic operating state diagram of the pixel unit of the display device according to an embodiment of the present disclosure;

FIG. 6 is another schematic operating state diagram of the pixel unit of the display device according to an embodiment of the present disclosure;

FIG. 7 is still another schematic operating state diagram of the pixel unit of the display device according to an embodiment of the present disclosure; and

FIG. 8 is yet still another schematic operating state diagram of the pixel unit of the display device according to an embodiment of the present disclosure.

Reference numerals and denotations thereof:

1000: electronic device; 100: display device; 10: pixel array; 11: pixel unit; 20: scanning line; 30: first drive module; 40: second drive module; Gn: scanning signal; GSn: reset signal; T1: first transistor; T2: second transistor; T3: third transistor; T4: fourth transistor; C1: first capacitor; C2: second capacitor; D_{OLED}: light-emitting element; VDD: power source positive voltage; VSS: power source negative voltage, N1: first node; N2: second node; G: gate; D: drain; S: source; DATA: data signal; INT: initialization signal; En: enable signal; Vref: reference potential; Vdata: data potential.

### DETAILED DESCRIPTION

The embodiments of the present disclosure are described in detail hereinafter. Examples of the described embodiments are given in the accompanying drawings, wherein the identical or similar reference numerals constantly denote the identical or similar elements or elements having the identical or similar functions. The specific embodiments described with reference to the attached drawings are all exemplary, and are intended to illustrate and interpret the present disclosure, which shall not be construed as causing limitations to the present disclosure.

In the description of some embodiments of the present disclosure, it should be understood that the terms “central,” “transversal,” “longitudinal,” “length,” “width,” “thickness,” “upper,” “lower,” “front,” “rear,” “left,” “right,” “vertical,” “horizontal,” “top,” “bottom,” “inner,” “outer,” “clockwise,” “counterclockwise,” and the like indicate orientations and position relationships which are based on the illustrations in the accompanying drawings, and these terms are merely for ease and brevity of the present disclosure, instead of indicating or implying that the devices or elements shall have a particular orientation and shall be structured and operated based on the particular orientation. Accordingly, these terms shall not be construed as limiting the present disclosure. In addition, terms of “first” and “second” are only used for description, but shall not be understood as indication or implication of relative importance or implicit indication of the number of the specific technical features. Therefore, the features defined by the terms “first” and “second” may explicitly or implicitly include one or more of these features. In the description of the present disclosure, the term “multiple” or “a plurality of” signifies at least two, unless otherwise specified.

In the description of the present disclosure, it should be noted that unless otherwise specified and defined, the terms “installed,” “coupled,” “connected” and derivative forms of these words shall be understood in a broad sense, which, for example, may be understood as fixed connection, detachable connection or integral connection; may be mechanical connection or electrical connection; or may be direct connection, indirect connection via an intermediate medium; or may be communication between two internal elements or interaction between these two elements. Persons of ordinary skill in the art may understand the specific meanings of the above terms in the present disclosure according to the actual circumstances and contexts.

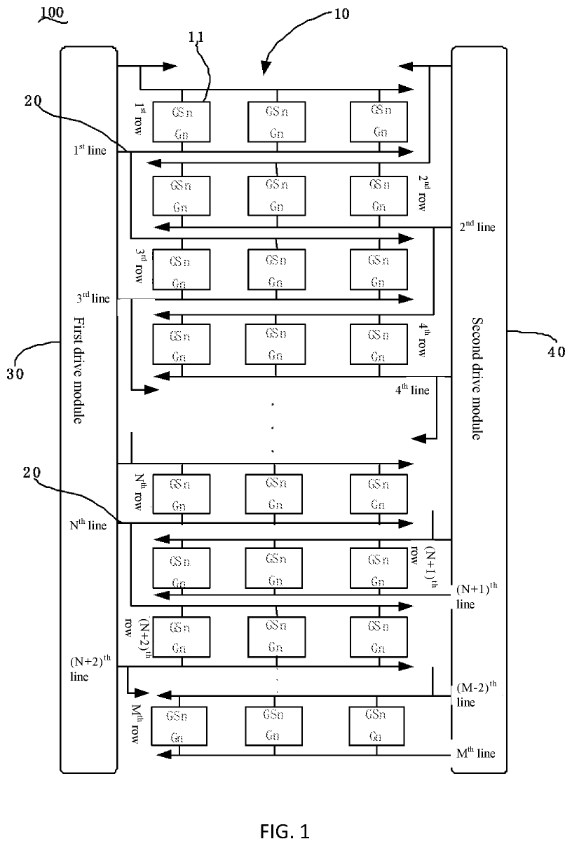

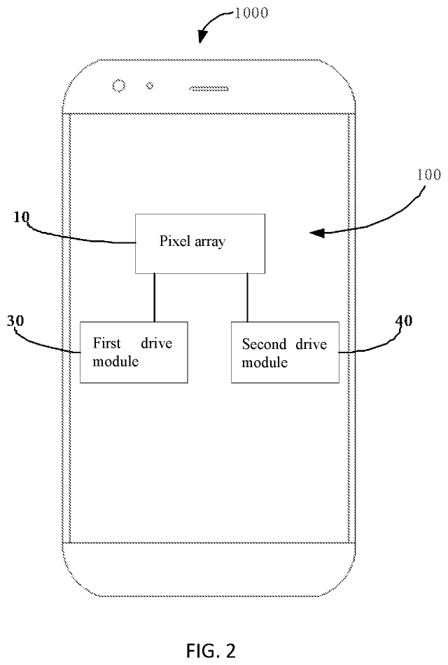

Referring to FIG. 1 and FIG. 2, a display device 100 according to an embodiment of the present disclosure is applicable to an electronic device 1000 according to an embodiment of the present disclosure. Or, the electronic device 1000 according to the embodiment of the present disclosure includes the display device 100 according to the embodiment of the present disclosure. The display device 100 according to the embodiment of the present disclosure may be a liquid crystal display (LCD), an organic light-emitting diode (OLED), or the like.

The electronic device 1000 according to the embodiment of the present disclosure includes, but is not limited to, a mobile phone, a tablet computer, a wearable smart device, a display, a vehicle-mounted terminal, a music player, a video player, a television, or the like. In an example as illustrated in FIG. 2, the electronic device 1000 is a mobile phone.

The display device 100 according to the embodiment of the present disclosure includes a pixel array 10, a scanning line 20, a first drive module 30, and a second drive module 40.

Referring to FIG. 1, the pixel array 10 includes M rows of pixel units 11, and the number of scanning lines 20 corresponds to the number of rows of pixel units 11, that is, the number of scanning lines 20 is M. An N^{th} scanning line 20 is connected to the pixel units 11 in an N^{th} row and the pixel units 11 in an (N+2)^{th} row and is configured to supply a scanning signal Gn to the pixel units 11 in the N^{th} row and supply a reset signal GSn to the pixel units 11 in the (N+2)^{th} row, wherein 1≤N, (N+2)≤M, and N and M are positive integers. That is, the scanning signal Gn of the pixel units 11 in the N^{th} row may serve as the reset signal GSn of the pixel units 11 in the (N+2)^{th} row.

It may be understood that in this embodiment, the scanning signal Gn and the reset signal GSn are both a pulse signal, the scanning signal Gn of the pixel units 11 in the N^{th} row and the reset signal GSn of the pixel units 11 in the (N+2)^{th} row are the same pulse signal. For example, in the example as illustrated in FIG. 1, the scanning signal Gn of the pixel units 11 in a 1^{st} row and the reset signal GSn of the pixel units 11 in a 3^{rd} row are the same pulse signal, and both supplied by a 1^{st} scanning line 20.

Still referring to FIG. 1, in the embodiment of the present disclosure, the first drive module 30 and the second drive module 40 may be both a gate driver on array (GOA) module, and the first drive module 30 and the second drive module 40 are respectively arranged on two opposite sides of the pixel array 10. For example, in the example as illustrated in FIG. 1, the two drive modules are respectively arranged on left and right sides of the pixel array 10. The first drive module 30 is connected to the scanning line 20 connected to the pixel units 11 in an odd row, and the second drive module 40 is connected to the scanning line 20 connected to the pixel units 11 in an even row.

It should be noted that in the example as illustrated in FIG. 1, M is an even number, and the scanning line 20 connected to the pixel units 11 in an M^{th} row is connected to the second drive module 40. It may be understood that in other examples, M may also be an odd number, which is not limited in the present disclosure.

The first drive module 30 and the second drive module 40 are each configured to transmit a pulse signal, and the pulse signals transmitted by these two drive modules are transmitted via the scanning line 20 to the pixel array 10 to serve as the scanning signal Gn and the reset signal Gsn of the pixel units 11.

Specifically, as illustrated in FIG. 1, in this embodiment, the first drive module 30 is connected to the scanning line 20 connected to the pixel units 11 in the odd row, and the scanning signal Gn and the reset signal GSn are supplied to the pixel units 11 in the odd row via the scanning line 20. The second drive module 40 is connected to the scanning line 20 connected to the pixel units 11 in the even row, and the scanning signal Gn and the reset signal GSn are supplied to the pixel units 11 in the even row via the scanning line 20.

It may be understood that, in other embodiments, the first drive module 30 may also be connected to the scanning line 20 connected to the pixel units 11 in the even row, and the second drive module 40 may also be connected to the scanning line 20 connected to the pixel units 11 in the odd row, such that the scanning signal Gn and the reset signal GSn are supplied to the pixel array 10.

In this embodiment, the pixel array 10 may also be continuously driven row by row, that is, the pixel units 11 are driven from the 1^{st} row until the pixel units 11 in the M^{th} row are driven. In this embodiment, the scanning signal Gn of the pixel units 11 in the N^{th} row is advanced by one pulse width relative to the scanning signal Gn of the pixel units 11 in the (N+2)^{th} row. In the meantime, the scanning signal Gn and the reset signal GSn of the pixel units 11 in each row have the same pulse width. To be specific, the scanning signal Gn transmitted by the N^{th} scanning line 20 is advanced by one pulse width relative to the scanning signal Gn transmitted by an (N+2)^{th} scanning line 20. It may be understood that the scanning signal Gn transmitted by the N^{th} scanning line 20 is the reset signal GSn of the pixel units 11 in the (N+2)^{th} row, and the scanning signal Gn transmitted by the (N+2)^{th} scanning line 20 is the scanning signal Gn of the pixel units 11 in the (N+2)^{th} row. Apparently, the reset signal GSn and the scanning signal Gn of the pixel units 11 in the (N+2)^{th} row have the same pulse width, and the reset signal GSn of the pixel units 11 in the (N+2)^{th} row is advanced by one pulse width relative to the scanning signal Gn of the pixel units in the (N+2)^{th} row.

In addition, it may be understood that the scanning signal Gn of the pixel units 11 in the N^{th} row is advanced by half of a pulse signal relative to the scanning signal Gn of the pixel units 11 in an (N+1)^{th} row, and the scanning signal Gn of the pixel units 11 in the (N+1)^{th} row is advanced by half of a pulse signal relative to the scanning signal Gn of the pixel units 11 in the (N+2)^{th} row. To be specific, the scanning signal Gn transmitted by the N^{th} scanning line 20 is advanced by half of a pulse width relative to the scanning signal Gn transmitted by the (N+1)^{th} scanning line 20, and the scanning signal Gn transmitted by the (N+1)^{th} scanning line 20 is advanced by half of a pulse width relative to the scanning signal Gn transmitted by the (N+2)^{th} scanning line 20.

It should be noted that, in this embodiment, the first drive module 30 and the second drive module 40 each include a pulse output terminal (not illustrated). The pulse output terminal of the first drive module 30 supplies the reset signal GSn to the pixel units 11 in the 1^{st} row, and the pulse output terminal of the second drive module 40 supplies the reset signal GSn to the pixel units 11 in a 2^{nd} row. It should be noted that, in other embodiments, the pulse output terminal of the first drive module 30 may supply the reset signal GSn to the pixel units 11 in the 2^{nd} row, and the pulse output terminal of the second drive module 40 may supply the reset signal GSn to the pixel units 11 in the 1^{st} row, which is not limited in the present disclosure.

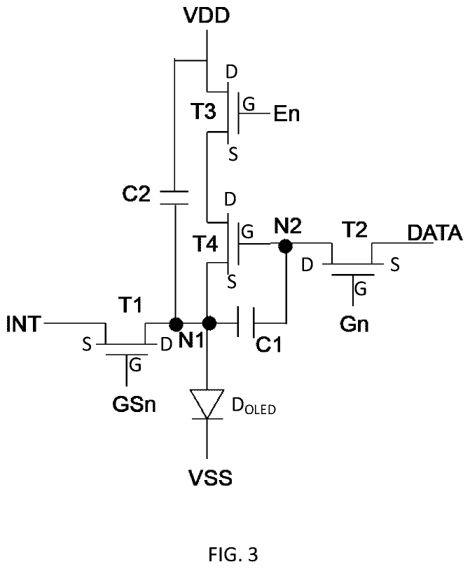

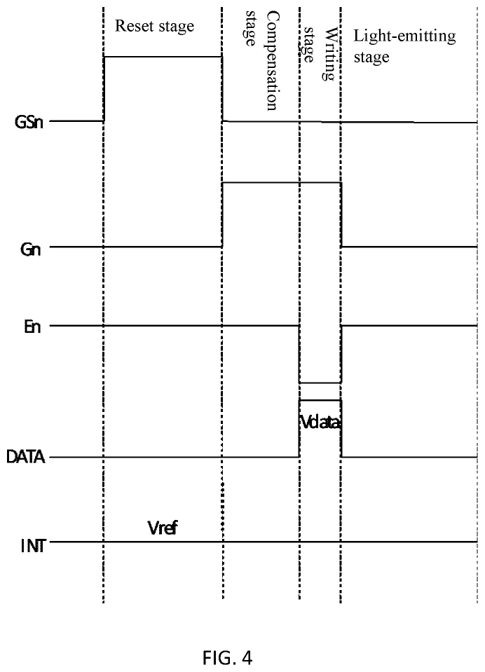

Referring to FIG. 3 and FIG. 4, each of the pixel units 11 of the pixel array 10 includes a first transistor T1, a second transistor T2, a third transistor T3, a fourth transistor T4, a first capacitor C1, a second capacitor C2, and a light-emitting element D_{OLED}.

In the embodiment of the present disclosure, each of the transistors may be a thin film transistor (TFT). Each of the transistors (T1 to T4) includes a gate G, a source S, and a drain D. In the embodiment as illustrated in the drawings, each of the transistors (T1 to T4) is an N-type thin film transistor. The thin film transistor includes a low-temperature polysilicon thin film transistor, an oxide semiconductor thin film transistor, and an amorphous silicon thin film transistor. Each of the transistors (T1 to T4) in this embodiment employs one or more of the listed transistors.

The light-emitting element D_{OLED} is an organic light-emitting diode (OLED). It may be understood that in other embodiments, each of the transistors (T1 to T4) may also be a P-type thin film transistor. In such a case, a voltage polarity of an input signal only needs to be reversed, that is, a high level is converted to a low level, and a low level is converted to a high level. In addition, in some embodiments, the light-emitting element D_{OLED} may also be an inorganic light-emitting diode, which is not limited in the present disclosure.

The gate G of the first transistor T1 is connected to the reset signal GSn, the source S of the first transistor T1 is connected to an initialization signal INT, and the drain D of the first transistor T1 is electrically connected to a first node N1. The gate G of the second transistor T2 is connected to the scanning signal Gn, the source S of the second transistor T2 is connected to a data signal DATA, and the drain D of the second transistor T2 is electrically connected to a second node N2. The gate G of the third transistor T3 is connected to an enable signal En, the source S of the third transistor T3 is electrically connected to the drain D of the fourth transistor T4, and the drain D of the third transistor T3 is electrically connected to a power source positive voltage VDD. The gate G of the fourth transistor T4 is electrically connected to the second node N2, the source S of the fourth transistor T4 is electrically connected to the first node N1, and the drain D of the fourth transistor T4 is electrically connected to the source S of the third transistor T3. One terminal of the first capacitor C1 is electrically connected to the first node N1, and the other terminal of the first capacitor C1 is electrically connected to the second node N2. One terminal of the second capacitor C2 is electrically connected to the power source positive voltage VDD, and the other terminal of the second capacitor C2 is electrically connected to the first node N1. An anode of the light-emitting element D_{OLED} is electrically connected to the first node N1, and a cathode of the light-emitting element D_{OLED} is electrically connected to a power source negative voltage VSS.

Specifically, the reset signal GSn is configured to control turn-on or turn-off of the first transistor T1. When the reset signal GSn is a high potential, the first transistor T1 is turned on; and when the reset signal GSn is a low potential, the first transistor T1 is turned off. The scanning signal Gn is configured to control turn-on or turn-off of the second transistor T2. When the scanning signal Gn is a high potential, the second transistor T2 is turned on; and when the scanning signal Gn is a low potential, the second transistor T2 is turned off. The enable signal En is configured to control turn-on or turn-off of the third transistor T3. When the enable signal En is a high potential, the third transistor T3 is turned on; and when the enable signal En is a low potential, the third transistor T3 is turned off. In addition, referring to FIG. 4, the initialization signal INT is a constant low potential, and the data signal DATA is a high-potential single pulse.

Referring to FIG. 4, a working process of the display device 100 includes a reset stage, a compensation stage, a writing stage, and a light-emitting stage of the pixel units 11. The scanning signal Gn, the reset signal GSn, the initialization signal INT, and the enable signal En operate according to the timing diagram as illustrated in FIG. 4 to correspond to the reset stage, the compensation stage, the writing stage, and the light-emitting stage.

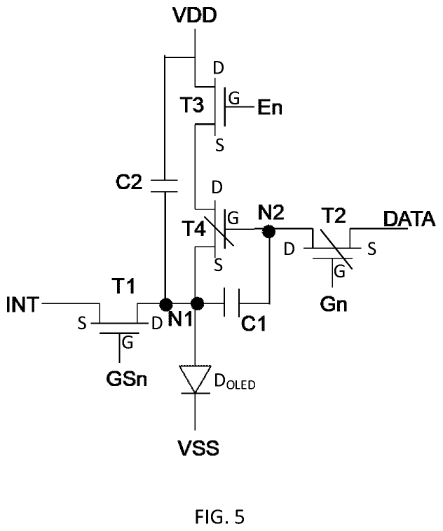

A specific operating process of the reset stage is as illustrated in FIG. 5. Specifically, in the reset stage, the reset signal GSn and the enable signal En are at a high potential, and the first transistor T1 and the third transistor T3 are turned on; the scanning signal Gn and the data signal DATA are at a low potential, and the second transistor T2 and the fourth transistor T4 are turned off; the initialization signal INT resets the first node N1 and charges the first capacitor C1 and the second capacitor C2. In the reset stage, the light-emitting element D_{OLED} does not emit light.

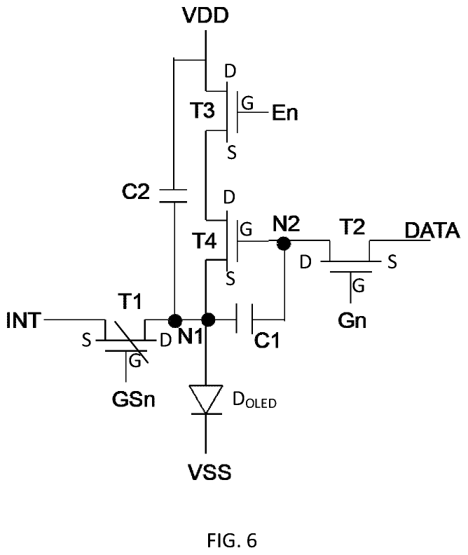

A specific operating process of the compensation stage is as illustrated in FIG. 6. Specifically, in the compensation stage, the scanning signal Gn and the enable signal En are at a high potential, and the second transistor T2, the third transistor T3, and the fourth transistor T4 are turned on; the reset signal GSn and the data signal DATA are at a low potential, and the first transistor T1 is turned off; and the data signal DATA transmits a reference potential Vref (that is, the low potential of the data signal DATA) to the second node N2. In this case, a potential of the first node N1 is a difference between the reference potential Vref and a threshold voltage of the fourth transistor T4. The threshold voltage of the fourth transistor T4 is a voltage difference between the gate G and the source S of the fourth transistor T4. In the compensation stage, the first capacitor C1 and the second capacitor C2 may be configured to maintain the voltage of the first node N1.

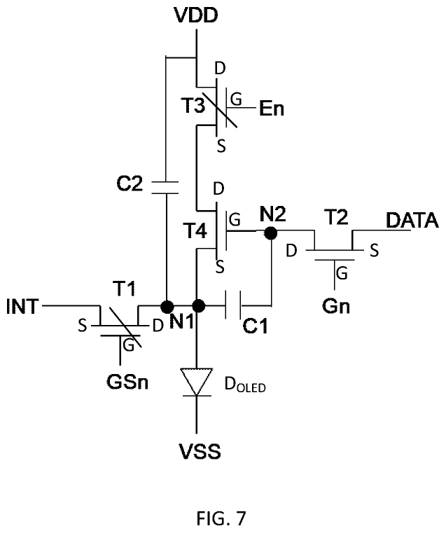

A specific operating process of the writing stage is as illustrated in FIG. 7. Specifically, in the writing stage, the scanning signal Gn and the data signal DATA are at a high potential, and the second transistor T2 and the fourth transistor T4 are turned on; the reset signal GSn and the enable signal En are at a low potential, the first transistor T1 and the third transistor T3 are turned off; and the data signal DATA transmits a data potential Vdata (that is, the high potential of the data signal DATA) to the second node N2. In the writing stage, the first capacitor C1 and the second capacitor C2 may also be configured to maintain the voltage of the first node N1.

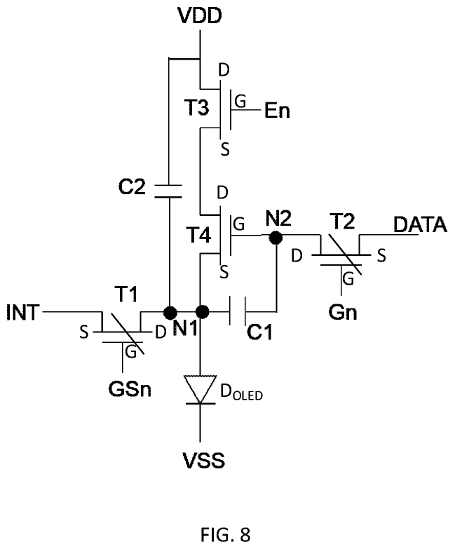

A specific operating process of the light-emitting stage is as illustrated in FIG. 8. Specifically, in the light-emitting stage, the enable signal En is at a high potential, and the scanning signal Gn, the reset signal GSn, and the data signal DATA are all at a low potential, and the third transistor T3 and the fourth transistor T4 are turned on, the first transistor T1 and the second transistor T2 are turned off, the power positive voltage VDD charges the first node N1, and the light-emitting element D_{OLED} emits light.

In summary, in the display device 100 and the electronic device 1000 according to the embodiments of the present disclosure, the N^{th} scanning line 20 may also supply the reset signal GSn to the pixel units 11 in the (N+2)^{th} row while supplying the scanning signal Gn to the pixel units 11 in the N^{th} row. In this way, there is no need to arrange two separate scanning lines 20 for the pixel units 11 in each row to supply the scanning signal Gn and the reset signal GSn to the pixel units 11 in each row. Therefore, circuit stages desired by the two drive modules may be reduced, such that the border of the display device 100 is made even narrower.

In the present disclosure, unless otherwise specified or defined, by defining that a first feature is arranged “above,” or “below,” or “beneath” a second feature, it means that the first feature is in direct contact with the second feature, or the first feature is in indirect contact with the second feature via another feature or an intermediate medium therebetween. In addition, by defining that a first feature is arranged “over” or “above” a second feature, it means that the first feature is rightly over the second feature or is obliquely above the second feature, or the horizontal height of the first feature is greater than that of the second feature. In addition, by defining that a first feature is arranged “under,” or “blow,” or “beneath” a second feature, it means that the first feature is rightly under the second feature or is obliquely below the second feature, or the horizontal height of the first feature is less than that of the second feature.

Disclosure hereinafter provides many different embodiments or examples to practice different structures of the present disclosure. For simplification of the disclosure of the present disclosure, parts and settings in specific examples are described hereinafter. Nevertheless, these examples are only intended to illustrate the present disclosure, instead of limiting the present disclosure. In addition, the reference numerals and/or reference letters may be repeated in different examples in the present disclosure. Such repetitions are intended to achieve simplification and clarity, and do not denote a relationship between the discussed embodiments and/or settings. Further, the present disclosure provides examples of various specific processes and materials. However, persons of ordinary skill in the art would note that other processes and/or other materials are also applicable.

In the description of the present specification, reference terms such as “an embodiment,” “some embodiments,” “examples,” “specific examples,” “some examples,” or the like are intended to refer to that the specific features, structures, materials, or characteristics which are described in combination with the embodiments or examples are included in at least one embodiment or example of the present disclosure. In this specification, schematic expressions of the above terms do not necessarily indicate the same embodiments or examples. In addition, the described specific features, structures, materials, or characteristics may be combined in any one or multiple embodiments or examples in a suitable way.

Although the embodiments of the present disclosure are described in detail above, persons or ordinary skill in the art may understand that without departing from the principle and intention of the present disclosure, various variations, modifications and replacements may be made to these embodiments, and the scope of the present disclosure is defined by the appended claims and their equivalents.

What is claimed is:

1. A display device, comprising:
a pixel array, comprising M rows of pixel units;
M scanning lines, an N^{th} scanning line being connected to the pixel units in an N^{th} row and the pixel units in an (N+2)^{th} row, 1≤N, (N+2)≤M, N and M being both a positive integer; and
a first drive module and a second drive module, one of the first drive module and the second drive module being connected to a scanning line connected to pixel units in an odd row and being configured to supply a scanning signal and a reset signal to the pixel units in the odd row via the scanning line, and the other of the first drive module and the second drive module being connected to a scanning line connected to pixel units in an even row and being configured to a scanning signal and a reset signal to the pixel units in the even row via the scanning line.

2. The display device according to claim 1, wherein the scanning signal supplied to the pixel units in the N^{th} row is advanced by a pulse width relative to the scanning signal supplied to the pixel units in the (N+2)^{th} row.

3. The display device according to claim 1, wherein the N^{th} scanning line is configured to supply the scanning signal to the pixel units in the N^{th} row and supply the reset signal to the pixel units in the (N+2)^{th} row.

4. The display device according to claim 1, wherein the scanning signal and the reset signal supplied to the pixel units have a same pulse width.

5. The display device according to claim 1, wherein the pixel unit comprises a first transistor, a second transistor, a third transistor, a fourth transistor, a first capacitor, a second capacitor, and a light-emitting element; wherein
a gate of the first transistor is connected to the reset signal, a source of the first transistor is connected to an initialization signal, and a drain of the first transistor is electrically connected to a first node;
a gate of the second transistor is connected to the scanning signal, a source of the second transistor is connected to a data signal, and a drain of the second transistor is electrically connected to a second node;
a gate of the third transistor is connected to an enable signal, a source of the third transistor is electrically connected to a drain of the fourth transistor, a drain of the third transistor is electrically connected to a power source positive voltage;
a gate of the fourth transistor is electrically connected to the second node, a source of the fourth transistor is electrically connected to the first node, and the drain of the fourth transistor is electrically connected to the source of the third transistor;
one terminal of the first capacitor is electrically connected to the first node, and the other terminal of the first capacitor is electrically connected to the second node;
one terminal of the second capacitor is electrically connected to the power source positive voltage, and the other terminal of the second capacitor is electrically connected to the first node; and
an anode of the light-emitting element is electrically connected to the first node, and a cathode of the light-emitting element is electrically connected to a power source negative voltage.

6. The display device according to claim 5, wherein a working process of the display device comprises a reset stage of the pixel units, wherein in the reset stage, the reset signal and the enable signal are at a first potential, and the scanning signal and the data signal are at a second potential, one of the first potential and the second potential is a high potential, and the other of the first potential and the second potential is a low potential.

7. The display device according to claim 5, wherein a working process of the display device comprises a compensation stage of the pixel units, wherein in the compensation stage, the scanning signal and the enable signal are at a first potential, and the reset signal and the data signal are at a second potential, one of the first potential and the second potential is a high potential, and the other of the first potential and the second potential is a low potential.

8. The display device according to claim 5, wherein a working process of the display device comprises a writing stage of the pixel units, wherein in the witting stage, the scanning signal and the data signal are at a first potential, and the reset signal and the enable signal are at a second potential, one of the first potential and the second potential is a high potential, and the other of the first potential and the second potential is a low potential.

9. The display device according to claim 5, wherein a working process of the display device comprises a light-emitting stage of the pixel units, wherein in the light-emitting stage, the enable signal is at a first potential, and the scanning signal, the reset signal, and the data signal are all at a second potential, one of the first potential and the second potential is a high potential, and the other of the first potential and the second potential is a low potential.

10. The display device according to claim 5, wherein at least one of the first transistor, the second transistor, the third transistor, and the fourth transistor is a thin film transistor.

11. The display device according to claim 5, wherein the initialization signal is a constant low potential, and the data signal is a high-potential single pulse;
or, the initialization signal is a constant high potential, and the data signal is a low-potential single pulse.

12. The display device according to claim 1, wherein the first drive module and the second drive module are respectively arranged on two opposite sides of the pixel array.

13. An electronic device, comprising a display device, wherein the display device comprises:
a pixel array, comprising M rows of pixel units;
M scanning lines, an N^{th} scanning line being connected to the pixel units in an N^{th} row and the pixel units in an (N+2)^{th} row, 1≤N, (N+2)≤M, N and M being both a positive integer; and
a first drive module and a second drive module, one of the first drive module and the second drive module being connected to a scanning line connected to pixel units in an odd row and being configured to supply a scanning signal and a reset signal to the pixel units in the odd row via the scanning line, and the other of the first drive module and the second drive module being connected to a scanning line connected to pixel units in an even row and being configured to a scanning signal and a reset signal to the pixel units in the even row via the scanning line.

14. The electronic device according to claim 13, wherein the scanning signal supplied to the pixel units in the N^{th} row is advanced by a pulse width relative to the scanning signal supplied to the pixel units in the (N+2)^{th} row.

15. The electronic device according to claim 13, wherein the N^{th} scanning line is configured to supply the scanning signal to the pixel units in the N^{th} row and supply the reset signal to the pixel units in the (N+2)^{th} row.

16. The electronic device according to claim 13, wherein the scanning signal and the reset signal supplied to the pixel units have a same pulse width.

17. The electronic device according to claim 13, wherein the pixel unit comprises a first transistor, a second transistor, a third transistor, a fourth transistor, a first capacitor, a second capacitor, and a light-emitting element; wherein
a gate of the first transistor is connected to the reset signal, a source of the first transistor is connected to an initialization signal, and a drain of the first transistor is electrically connected to a first node;
a gate of the second transistor is connected to the scanning signal, a source of the second transistor is connected to a data signal, and a drain of the second transistor is electrically connected to a second node;
a gate of the third transistor is connected to an enable signal, a source of the third transistor is electrically connected to a drain of the fourth transistor, a drain of the third transistor is electrically connected to a power source positive voltage;
a gate of the fourth transistor is electrically connected to the second node, a source of the fourth transistor is electrically connected to the first node, and the drain of the fourth transistor is electrically connected to the source of the third transistor;
one terminal of the first capacitor is electrically connected to the first node, and the other terminal of the first capacitor is electrically connected to the second node;
one terminal of the second capacitor is electrically connected to the power source positive voltage, and the other terminal of the second capacitor is electrically connected to the first node; and
an anode of the light-emitting element is electrically connected to the first node, and a cathode of the light-emitting element is electrically connected to a power source negative voltage.

18. The electronic device according to claim 17, wherein a working process of the display device comprises a reset stage of the pixel units, wherein in the reset stage, the reset signal and the enable signal are at a first potential, and the scanning signal and the data signal are at a second potential, one of the first potential and the second potential is a high potential, and the other of the first potential and the second potential is a low potential.

19. The electronic device according to claim 17, wherein a working process of the display device comprises a compensation stage of the pixel units, wherein in the compensation stage, the scanning signal and the enable signal are at a first potential, and the reset signal and the data signal are at a second potential, one of the first potential and the second potential is a high potential, and the other of the first potential and the second potential is a low potential.

20. The electronic device according to claim 17, wherein a working process of the display device comprises a writing stage of the pixel units, wherein in the witting stage, the scanning signal and the data signal are at a first potential, and the reset signal and the enable signal are at a second potential, one of the first potential and the second potential is a high potential, and the other of the first potential and the second potential is a low potential; and
the working process of the display device further comprises a light-emitting stage of the pixel units, wherein in the light-emitting stage, the enable signal is at the first potential, and the scanning signal, the reset signal, and the data signal are all at the second potential.
